(19) United States
(12) Patent Application Publication
(10) Pub. No.: US 2026/0149450 A1
(43) Pub. Date: May 28, 2026

(54) SEMICONDUCTOR RELAY AND SEMICONDUCTOR RELAY MANUFACTURING METHOD

(71) Applicant: Panasonic Intellectual Property Management Co., Ltd., Osaka (JP)

(72) Inventors: Ryosuke MAEDA, Kyoto (JP); Noboru NEGORO, Osaka (JP)

(21) Appl. No.: 19/121,746

(22) PCT Filed: Jul. 6, 2023
(86) PCT No.: PCT/JP2023/025124

§ 371 Date: Apr. 16, 2025

(30) Foreign Application Priority Data
Nov. 25, 2022 (JP) 2022-188551

(51) Int. Cl. H03K 17/693; H03K 17/51

(52) U.S. Cl. CPC H03K 17/693; H03K 2017/515; H03K 2217/0054

(57) ABSTRACT

A semiconductor relay includes input terminals, output terminals, a semiconductor element that provides electrical conduction and interruption between the output terminals in response to an electric signal given to the input terminals, and a capacitive element connected between the output terminals. The capacitive element has a capacitance larger than a capacitance between the output terminals included in semiconductor element, and the capacitive element has an inductance smaller than an inductance between the output terminals included in semiconductor element.

### TECHNICAL FIELD

The present disclosure relates to a semiconductor relay and a semiconductor relay manufacturing method, and particularly relates to a semiconductor relay having improved high-pass characteristics.

### BACKGROUND ART

With an increase in frequency of operation clocks of semiconductor devices, an improvement in high-pass characteristics is required for semiconductor relays, such as PhotoMOS relays, which are used between a pulse driver in a semiconductor tester for testing a semiconductor device and the device under test (DUT).

Conventionally, techniques for improving the high-pass characteristics of semiconductor relays have been proposed (see Patent Literature (PTL) 1). PTL 1 improves high-pass characteristics by reducing the parasitic inductance included in a semiconductor relay having a structure in which a light receiving element is stacked on a MOSFET, further a light emitting element is stacked on the light receiving element, and these elements are wired while a rear surface drain of the MOSFET is provided by surface mounting.

### CITATION LIST

### Patent Literature

[PTL 1] Japanese Unexamined Patent Application Publication No. 2020-88091

### SUMMARY OF INVENTION

### Technical Problem

However, the semiconductor relay disclosed in PTL 1 has a complex structure, which leads to problems such as complicated steps needed for manufacturing and high manufacturing costs.

Accordingly, an object of the present disclosure is to provide a semiconductor relay that has a simple configuration, has improved high-pass characteristics, and is inexpensive, and a method for manufacturing the semiconductor relay.

### Solution to Problem

To achieve the above object, the semiconductor relay according to one embodiment of the present disclosure includes input terminals including a first terminal and a second terminal; output terminals including a third terminal and a fourth terminal; a semiconductor element that provides electrical conduction and interruption between the output terminals in response to an electric signal given between the input terminals; and a capacitive element connected between the output terminals. Here, the capacitive element has a capacitance larger than a capacitance between the output terminals included in the semiconductor element, and the capacitive element has an inductance smaller than an inductance between the output terminals included in the semiconductor element.

To achieve the above object, the semiconductor relay manufacturing method according to one embodiment of the present disclosure is a method of manufacturing the semiconductor relay, including determining a capacitance and an inductance that the capacitive element included in the semiconductor relay should have; and manufacturing the semiconductor relay using the capacitive element having the capacitance and the inductance determined. Here, in the determining, a passband of the semiconductor relay is calculated using a resonance frequency of the semiconductor relay in a low frequency range and a resonance frequency of the semiconductor relay in a high frequency range that are determined depending on the capacitance and the inductance that the capacitive element has, and the capacitance and inductance that the capacitive element should have are determined to make the passband calculated a desired passband.

### Advantageous Effects of Invention

The present disclosure provides a semiconductor relay that has a simple configuration, has improved high-pass characteristics, and is inexpensive, and a method of manufacturing the semiconductor relay.

### BRIEF DESCRIPTION OF DRAWINGS

FIG. 1 is a circuit diagram illustrating a configuration of a semiconductor relay according to Embodiment 1.

FIG. 2 is an equivalent circuit diagram of the semiconductor relay illustrated in FIG. 1.

FIG. 3 is a diagram for illustrating the pass characteristics of the semiconductor relay illustrated in FIG. 1.

FIG. 4 is a diagram for illustrating a method of designing the passband of a semiconductor relay according to Embodiment 1.

FIG. 5A is an appearance view of the semiconductor relay according to Example 1.

FIG. 5B is a schematic configurational view illustrating an example of the inner structure of the semiconductor element illustrated in FIG. 5A.

FIG. 6 is a schematic configurational view illustrating an example of the inner structure of a semiconductor relay according to Example 2.

FIG. 7 is a schematic configurational view illustrating an example of the inner structure of a semiconductor relay according to Example 3.

FIG. 8 is a schematic configurational view illustrating an example of the inner structure of a semiconductor relay according to Example 4.

FIG. 9A is a schematic configurational view illustrating an example of the inner structure of a semiconductor relay according to Example 5.

FIG. 9B is a diagram illustrating an example of the structure of a capacitive element included in the semiconductor relay according to Example 5.

FIG. 10 is a circuit diagram illustrating a configuration of a semiconductor relay according to Embodiment 2.

FIG. 11 is a diagram for illustrating the pass characteristics of the semiconductor relay illustrated in FIG. 10.

FIG. 12 is an appearance view of a semiconductor relay according to Example 6.

FIG. 13 is a schematic configurational view illustrating an example of the inner structure of a semiconductor relay according to Example 7.

FIG. 14 is a schematic configurational view illustrating an example of the inner structure a semiconductor relay according to Example 8.

FIG. 15 is a schematic configurational view illustrating an example of the inner structure of a semiconductor relay according to Example 9.

FIG. 16 is a diagram for illustrating a semiconductor relay manufacturing method according to an embodiment.

FIG. 17 is a diagram for illustrating the susceptance in an equivalent circuit of a semiconductor relay according to an embodiment.

FIG. 18 is a diagram for illustrating the frequency at which two susceptances appearing in the equivalent circuit of the semiconductor relay according to the embodiment reach 0 siemens.

FIG. 19 is a diagram for illustrating a method of determining the bandwidth to be used.

FIG. 20 is a diagram illustrating a specific example of the pass characteristics of a semiconductor relay in which the capacitance and inductance which the capacitive element should have are determined by Step S10 (S10a to S10c) in (a) of FIG. 16.

### DESCRIPTION OF EMBODIMENTS

Hereinafter, embodiments according to the present disclosure will be described in detail with reference to the drawings. The embodiments described below all illustrate one specific examples of the present disclosure. Numeric values, shapes, materials, components, arrangement positions of components and connection forms thereof, steps, order of steps, and the like shown in the embodiments below are exemplary, and should not be construed as limitations to the present disclosure. The drawings are not always strictly drawn. In the drawings, identical reference numerals are given to substantially identical configurations, and the duplication of the description will be omitted or simplified. The expression “A and B are connected” means that A and B are electrically connected, and encompasses not only the case where A and B are directly connected, but also the case where A and B are indirectly connected with another circuit entity interposed between A and B.

### Embodiment 1

First, a semiconductor relay according to Embodiment 1 will be described.

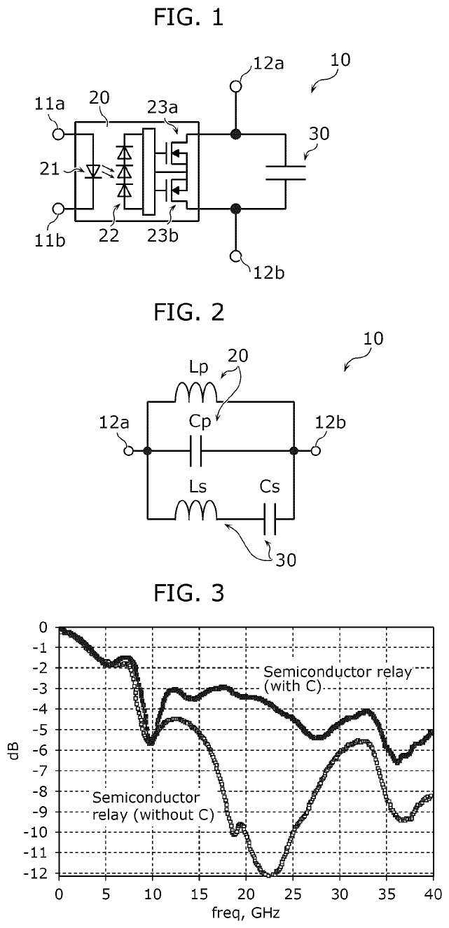

FIG. 1 is a circuit diagram illustrating a configuration of semiconductor relay 10 according to Embodiment 1. Semiconductor relay 10 includes input terminals 11a and 11b including first terminal 11a and second terminal 11b, output terminals 12a and 12b including third terminal 12a and fourth terminal 12b, semiconductor element 20 that provides electrical conduction and interruption between output terminals 12a and 12b in response to an electric signal given between input terminals 11a and 11b, and capacitive element 30 connected between output terminals 12a and 12b. Capacitive element 30 has a capacitance larger than the capacitance between output terminals 12a and 12b included in semiconductor element 20, and capacitive element 30 has an inductance smaller than the inductance between output terminals 12a and 12b included in semiconductor element 20.

Here, in the present embodiment, semiconductor element 20 is a PhotoMOS relay, and is configured with light emitting element 21 connected between input terminals 11a and 11b, light receiving element 22 that receives light from light emitting element 21, and two MOSFETs 23a and 23b that are outputters controlled by light receiving element 22 to be turn on/off. MOSFET 23a is an n-channel MOSFET, in which the drain is connected to third terminal 12a, the gate is connected to light receiving element 22, and the source is connected to the source of MOSFET 23b. MOSFET 23b is an n-channel MOSFET, in which the drain is connected to fourth terminal 12b, the gate is connected to light receiving element 22, and the source is connected to the source of MOSFET 23a. When a current/voltage under a predetermined condition is applied between input terminals 11a and 11b, light emission from light emitting element 21 causes two MOSFETs 23a and 23b to be turned on, generating an electrical conducted state between output terminals 12a and 12b. To be noted, semiconductor element 20 constituting semiconductor relay 10 according to the present disclosure is not limited to a PhotoMOS relay, and may be a solid-state relay including a TRIAC instead of the MOSFET in the outputter.

In other words, as a feature, semiconductor relay 10 according to the present embodiment has a configuration in which capacitive element 30 having a low inductance is connected in parallel to semiconductor element 20, such as a PhotoMOS relay, thereby shifting the resonant point of semiconductor element 20. This feature will be described in detail with reference to FIGS. 2 to 4.

FIG. 2 is an equivalent circuit diagram of semiconductor relay 10 illustrated in FIG. 1. Semiconductor relay 10 is represented by an equivalent circuit of three circuit entities connected in parallel between output terminals 12a and 12b, i.e., (1) inductance Lp that semiconductor element 20 has, (2) capacitance Cp that semiconductor element 20 has, and (3) capacitance Cs and inductance Ls that capacitive element 30 has. Here, (1) inductance Lp that semiconductor element 20 has is substantially the inductance of MOSFETs 23a and 23b constituting semiconductor element 20 or the inductance included in a wire connecting MOSFETs 23a and 23b. On the other hand, (2) capacitance Cp that semiconductor element 20 has is substantially the capacitance that a lead frame (not illustrated) constituting semiconductor element 20 has.

The present embodiment satisfies a condition that capacitive element 30 has capacitance Cs larger than capacitance Cp that semiconductor element 20 has and capacitive element 30 has inductance Ls smaller than inductance Lp that semiconductor element 20 has.

FIG. 3 is a diagram for illustrating the pass characteristics of semiconductor relay 10 illustrated in FIG. 1. The abscissa represents the frequency, and the ordinate represents the insertion loss (dB; the loss is larger in the lower portion of the ordinate). The diagram illustrates the pass characteristics of semiconductor relay 10 according to the present embodiment (graph of “Semiconductor relay (with C)”) and the pass characteristics of a standard semiconductor relay without a capacitive element according to Reference Example (graph of “Semiconductor relay (without C)”).

As clearly shown in the drawing, in 10 GHz to 30 GHz as an example of the target bandwidth to be used, the pass characteristics of semiconductor relay 10 according to the present embodiment are more significantly improved than those of semiconductor relay according to Reference Example.

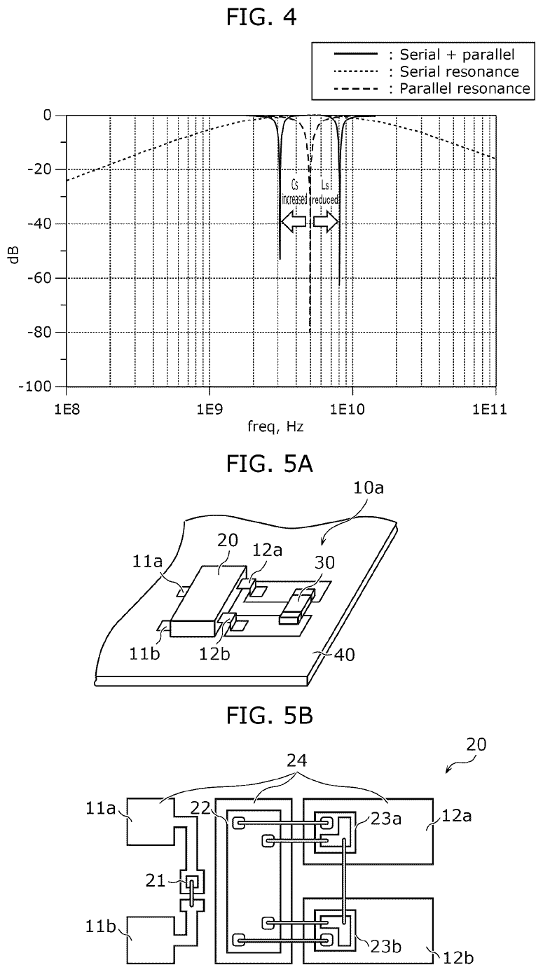

FIG. 4 is a diagram for illustrating a method of designing the passband of semiconductor relay 10 according to Embodiment 1. This diagram illustrates the pass characteristics of the parallel resonance by inductance Lp and capacitance Cp that semiconductor element 20 has (graph of “Parallel resonance”), the pass characteristics of the serial resonance by capacitance Cs and inductance Ls that capacitive element 30 has (graph of “Serial resonance”), and the pass characteristics of the resonance caused by the parallel resonance by inductance Lp and capacitance Cp that semiconductor element 20 has and the serial resonance by capacitance Cs and inductance Ls that capacitive element 30 has (graph of “Serial+parallel”). The abscissa represents the frequency, and the ordinate represents the insertion loss (dB; the loss is larger in the lower portion of the ordinate).

As illustrated in the equivalent circuit in FIG. 2, by connecting capacitive element 30 to semiconductor element 20 in parallel, semiconductor relay 10 according to the present embodiment demonstrates (1) an effect that capacitance Cs that capacitive element 30 has is connected in parallel to a parallel circuit of inductance Lp and capacitance Cp that semiconductor element 20 has, and (2) an effect that inductance Ls that capacitive element 30 has is connected in parallel to a parallel circuit of inductance Lp and capacitance Cp that semiconductor element 20 has. This causes parallel resonance at two frequencies.

In other words, by connecting capacitive element 30 in parallel to semiconductor element 20, as illustrated in FIG. 4, the resonance frequency in a low frequency range shifts to a lower frequency range due to an increase in capacitance Cs. Specifically, to obtain 1/A of the resonance frequency, capacitance Cs is controlled to satisfy Cs≈A²·Cp. On the other hand, the resonance frequency in a high frequency shifts to a higher frequency range due to a reduction in synthetic inductance caused by parallel connection of inductance Ls. Specifically, to obtain A-fold of the resonance frequency, inductance Ls is controlled to satisfy Ls≈Lp/A².

Thus, the passband of semiconductor relay 10 can be designed to a desired bandwidth by determining capacitance Cs and inductance Ls that capacitive element 30 has, to move the resonance frequency in a low frequency range and the resonance frequency in a high frequency range out of the target bandwidth to be used, i.e., 10 GHz to 30 GHz, for example.

As described above, in semiconductor relay 10 according to Embodiment 1, capacitive element 30 having a low inductance is connected in parallel to semiconductor element 20 that provides electrical conduction and interruption between output terminals 12a and 12b in response to an electric signal given between input terminals 11a and 11b. Thereby, the resonance point that semiconductor element 20 has can be shifted, and capacitive element 30 can pass a signal in a desired high frequency bandwidth. On the other hand, semiconductor element 20 can be an inexpensive one having low performance because it passes only a low frequency signal. As a result, semiconductor relay 10 that is inexpensive and has a simple configuration and improved high-pass characteristics is implemented. When it is unnecessary to pass a low frequency signal (particularly DC), pass of a signal in a high frequency bandwidth can be implemented by a semiconductor relay configured with only capacitive element 30.

Hereinafter, Examples 1 to 5 will be described as specific implementation examples of semiconductor relay 10 according to Embodiment 1.

### Example 1

FIG. 5A is an appearance view of semiconductor relay 10a according to Example 1. This view illustrates the state where semiconductor relay 10a is mounted on printed circuit substrate 40. In semiconductor relay 10a, semiconductor element 20 as a single-chip semiconductor part and capacitive element 30 as a chip part are connected through a wiring pattern on printed circuit substrate 40.

Semiconductor relay 10a according to the present example has a feature that capacitive element 30 is disposed outside semiconductor element 20. Thereby, semiconductor relay 10a can be easily manufactured by a step of mounting parts on printed circuit substrate 40.

FIG. 5B is a schematic configurational view illustrating an example of the inner structure of semiconductor element 20 (here, PhotoMOS relay) illustrated in FIG. 5A. This view illustrates light emitting element 21, light receiving element 22, two MOSFETs 23a and 23b, bonding wires connecting these, and lead frame 24 supporting these. In this example, input terminals 11a and 11b and output terminals 12a and 12b are formed with lead frame 24 of semiconductor element 20.

### Example 2

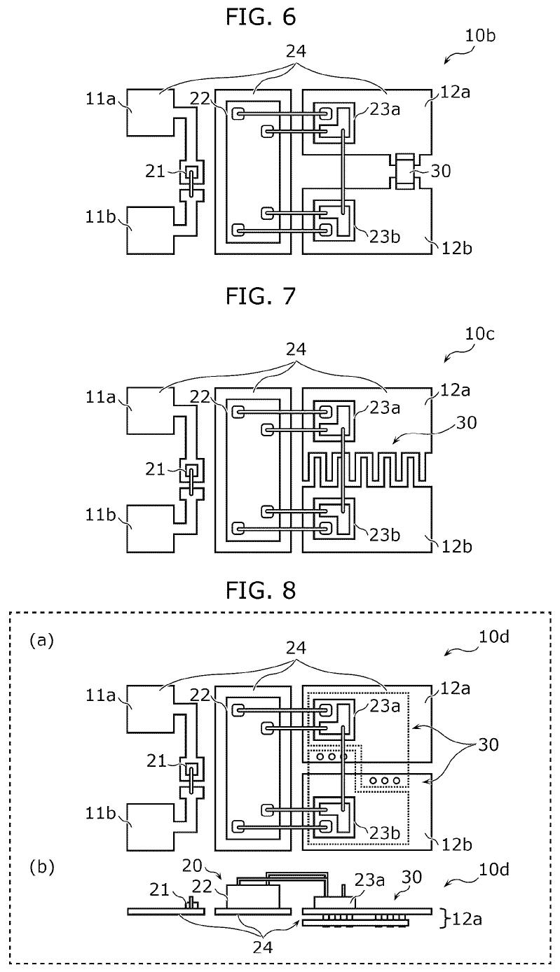

FIG. 6 is a schematic configurational view illustrating an example of the inner structure of semiconductor relay 10b according to Example 2.

In semiconductor relay 10b according to the present example, capacitive element 30 is disposed inside semiconductor element 20. More specifically, capacitive element 30 is a chip part, and is soldered between output terminals 12a and 12b formed with lead frame 24 of semiconductor element 20. This leads to implementation of semiconductor relay 10b having a smaller size than a semiconductor relay in which capacitive element 30 is disposed outside semiconductor element 20, and such a configuration as a single device allows more specific design of the device.

### Example 3

FIG. 7 is a schematic configurational view illustrating an example of the inner structure of semiconductor relay 10c according to Example 3.

In semiconductor relay 10c according to the present example, capacitive element 30 is disposed inside semiconductor element 20 and formed with lead frame 24 of semiconductor element 20. More specifically, capacitive element 30 according to the present example is implemented by forming output terminals 12a and 12b formed with lead frame 24 into comb-teethed electrodes opposed to each other with a gap interposed therebetween in a planar view. Thereby, output terminals 12a and 12b formed with lead frame 24 form capacitive element 30, the capacitive element such as a chip part is unnecessary, and semiconductor relay 10c having a small size is implemented. In addition, such a configuration as a single device allows more specific design of the device.

### Example 4

FIG. 8 is a schematic configurational view illustrating an example of the inner structure of semiconductor relay 10d according to Example 4. More specifically, (a) of FIG. 8 is a top surface view illustrating an example of the inner structure of semiconductor relay 10d, and (b) of FIG. 8 is a side view illustrating an example of the inner structure of semiconductor relay 10d illustrated in (a) of FIG. 8.

In semiconductor relay 10d according to the present example, capacitive element 30 is disposed inside semiconductor element 20 and formed with lead frame 24 of semiconductor element 20. More specifically, as illustrated in (b) of FIG. 8, capacitive element 30 according to the present example is implemented by forming output terminals 12a and 12b formed with lead frame 24 as overlapped electrodes opposed to each other with a gap interposed therebetween in a cross-sectional view. Thereby, output terminals 12a and 12b formed with lead frame 24 form capacitive element 30, the capacitive element such as a chip part is unnecessary, and semiconductor relay 10d having a small size is implemented. In addition, such a configuration as a single device allows more specific design of the device.

### Example 5

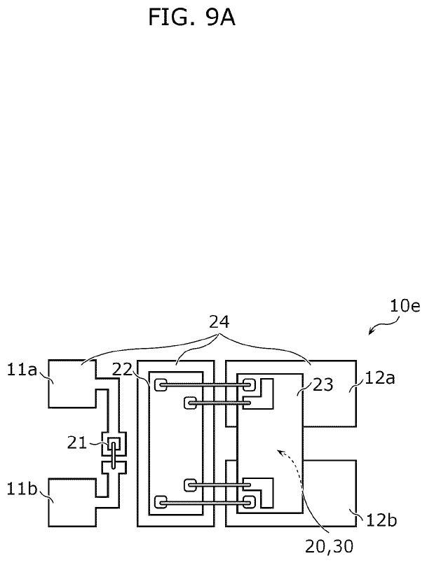

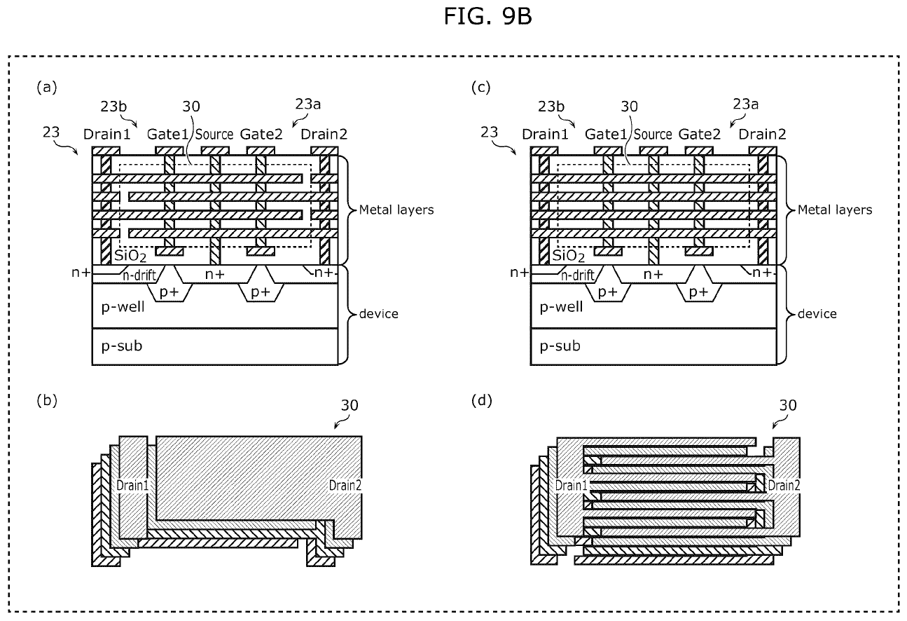

FIG. 9A is a schematic configurational view illustrating an example of the inner structure of semiconductor relay 10e according to Example 5.

In semiconductor relay 10e according to the present example, semiconductor element 20 includes semiconductor chip 23 including MOSFETs 23a and 23b, and capacitive element 30 is formed inside semiconductor chip 23.

FIG. 9B is a diagram illustrating an example of the structure of capacitive element 30 included in semiconductor relay 10e according to Example 5. More specifically, (a) and (b) of FIG. 9B are a cross-sectional view and a top surface view of semiconductor chip 23, respectively, when capacitive element 30 is formed as a Metal-Insulator-Metal (MIM) capacitance inside semiconductor chip 23, and (c) and (d) of FIG. 9B are a cross-sectional view and a top surface view of semiconductor chip 23, respectively, when capacitive element 30 is formed as a Metal-Oxide-Metal (MOM) capacitance inside semiconductor chip 23. In (a) to (d) of FIG. 9B, two MOSFETs 23a and 23b included in semiconductor chip 23 constitute a bidirectional switch formed by connecting the sources of these MOXFETs.

Thus, in semiconductor relay 10e according to the present example, capacitive element 30 is formed inside semiconductor chip 23 constituting semiconductor element 20, thereby implementing semiconductor relay 10e having a small size. In addition, such a configuration as a single device allows more specific design of the device.

### Embodiment 2

Next, a semiconductor relay according to Embodiment 2 will be described.

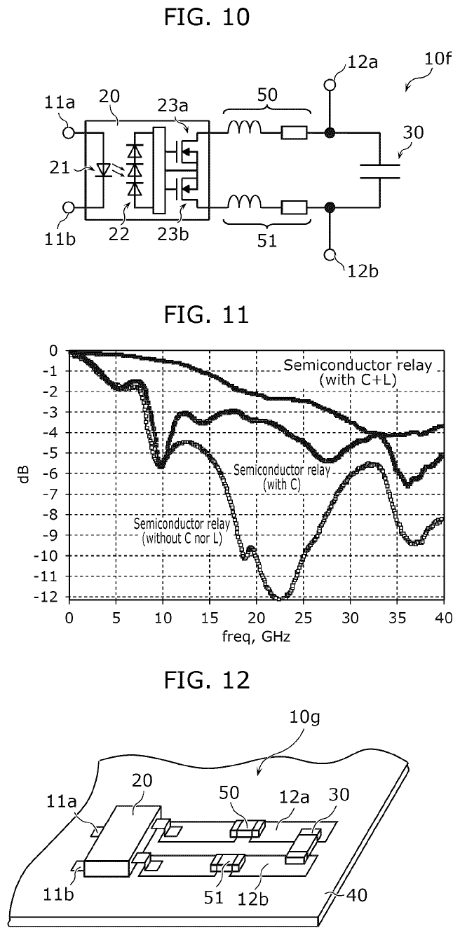

FIG. 10 is a circuit diagram illustrating a configuration of semiconductor relay 10f according to Embodiment 2.

Semiconductor relay 10f according to the present embodiment has a configuration including semiconductor relay 10 according to Embodiment 1 and inductance elements 50 and 51 added between output terminal 12a and MOSFET 23a and between output terminal 12b and MOSFET 23b, respectively.

FIG. 11 is a diagram for illustrating the pass characteristics of semiconductor relay 10f illustrated in FIG. 10. The abscissa represents the frequency, and the ordinate represents the insertion loss (dB; the loss is larger in the lower portion of the ordinate). This diagram illustrates the pass characteristics of semiconductor relay 10f according to the present embodiment (graph of “Semiconductor relay (with C+L)”), the pass characteristics of semiconductor relay 10 according to Embodiment 1 (graph of “Semiconductor relay (with C)”), and the pass characteristics of a standard semiconductor relay according to Reference Example without a capacitive element (graph of “Semiconductor relay (without C nor L)”).

As clearly shown in the drawing, compared with the semiconductor relay according to Reference Example, semiconductor relay 10f according to the present embodiment has significantly improved pass characteristics in 10 GHz to 30 GHz as an example of the target bandwidth to be used, and compared with semiconductor relay 10 according to Embodiment 1, semiconductor relay 10f according to the present embodiment has further improved pass characteristics in a wider frequency bandwidth.

More specifically, inductance elements 50 and 51 are inductors, resistors, or ferrite beads, and have a sufficiently high impedance value in a frequency bandwidth to be used. Such a configuration reduces influences over semiconductor element 20 (here, PhotoMOS relay) at a high frequency. Since it is sufficient that semiconductor element 20 passes only a low frequency signal, an inexpensive PhotoMOS relay having low performance or the like can be used.

Thus, semiconductor relay 10f according to Embodiment 2 includes inductance elements 50 and 51 that are inductors, resistors, or ferrite beads connected in series to semiconductor element 20, between output terminals 12a and 12b. Thereby, semiconductor relay 10f according to Embodiment 2 has further improved pass characteristics in a wider frequency bandwidth, compared to the semiconductor relay according to Reference Example and semiconductor relay 10 according to Embodiment 1.

Hereinafter, Examples 6 to 8 will be described as specific implementation examples of semiconductor relay 10f according to Embodiment 2.

### Example 6

FIG. 12 is an appearance view of semiconductor relay 10g according to Example 6. This view illustrates a state where semiconductor relay 10g is mounted on printed circuit substrate 40. In semiconductor relay 10g, semiconductor element 20 as a single-chip semiconductor part, inductance elements 50 and 51 as chip parts, and capacitive element 30 are connected through a wiring pattern on printed circuit substrate 40.

Semiconductor relay 10g according to the present example has a feature that inductance elements 50 and 51 are arranged outside semiconductor element 20. Thereby, semiconductor relay 10g can be easily manufactured by a step of mounting parts on printed circuit substrate 40.

### Example 7

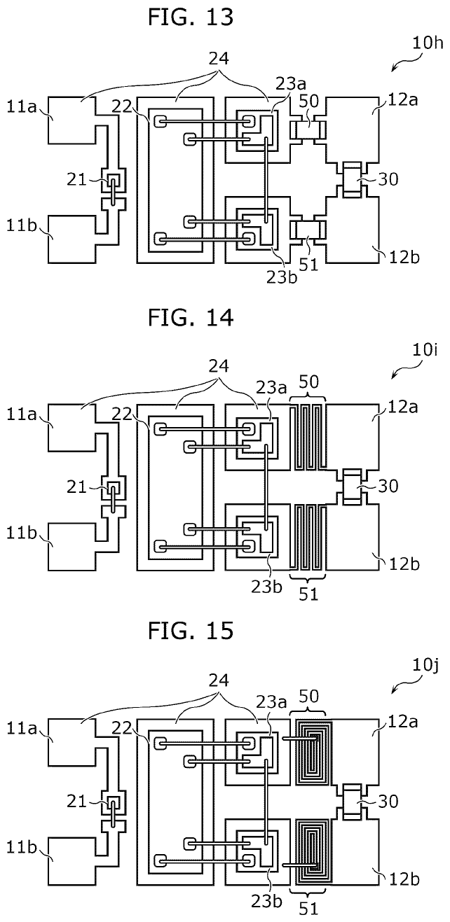

FIG. 13 is a schematic configurational view illustrating an example of the inner structure of semiconductor relay 10h according to Example 7.

In semiconductor relay 10h according to the present example, inductance elements 50 and 51 are arranged inside semiconductor element 20. Capacitive element 30 is incorporated in semiconductor element 20 as in Example 2.

In the present example, inductance elements 50 and 51 are chip parts, and are soldered between lead frame 24 connected to the drain of MOSFET 23a in semiconductor element 20 and lead frame 24 connected to one end of capacitive element 30 and between lead frame 24 connected to the drain of MOSFET 23b in semiconductor element 20 and lead frame 24 connected to the other end of capacitive element 30, respectively. This leads to implementation of semiconductor relay 10h having a smaller size than a semiconductor relay in which inductance elements 50 and 51 are arranged outside semiconductor element 20, and such a configuration as a single device allows more specific design of the device.

### Example 8

FIG. 14 is a schematic configurational view illustrating an example of the inner structure of semiconductor relay 10i according to Example 8.

In semiconductor relay 10i according to the present example, inductance elements 50 and 51 are arranged inside semiconductor element 20 and formed with lead frame 24 included in semiconductor element 20. More specifically, inductance elements 50 and 51 are implemented by lead frame 24 in the form of a meandered coil that connects the drain of MOSFET 23a in semiconductor element 20 to one end of capacitive element 30 and lead frame 24 in the form of a meandered coil that connects the drain of MOSFET 23b in semiconductor element 20 to the other end of capacitive element 30, respectively.

Thereby, lead frame 24 included in semiconductor element 20 forms inductance elements 50 and 51, the inductance element such as a chip part is unnecessary, and semiconductor relay 10i having a small size is implemented. In addition, such a configuration as a single device allows more specific design of the device.

### Example 9

FIG. 15 is a schematic configurational view illustrating an example of the inner structure of semiconductor relay 10j according to Example 9.

In semiconductor relay 10j according to the present example, inductance elements 50 and 51 are arranged inside semiconductor element 20 and formed with lead frame 24 included in semiconductor element 20. More specifically, inductance elements 50 and 51 are implemented by connecting the drain of MOSFET 23a in semiconductor element 20 and one end of capacitive element 30 with lead frame 24 in a spiral form and a bonding wire and by connecting the drain of MOSFET 23b in semiconductor element 20 and the other end of capacitive element 30 with lead frame 24 in a spiral form and a bonding wire, respectively.

Thereby, lead frame 24 included in semiconductor element 20 forms inductance elements 50 and 51, an inductance element such as a chip part is unnecessary, and semiconductor relay 10j having a small size is implemented. In addition, such a configuration as a single device allows more specific design of the device.

### (Semiconductor Relay Manufacturing Method)

Next, a method of manufacturing semiconductor relay 10 according to an embodiment will be described.

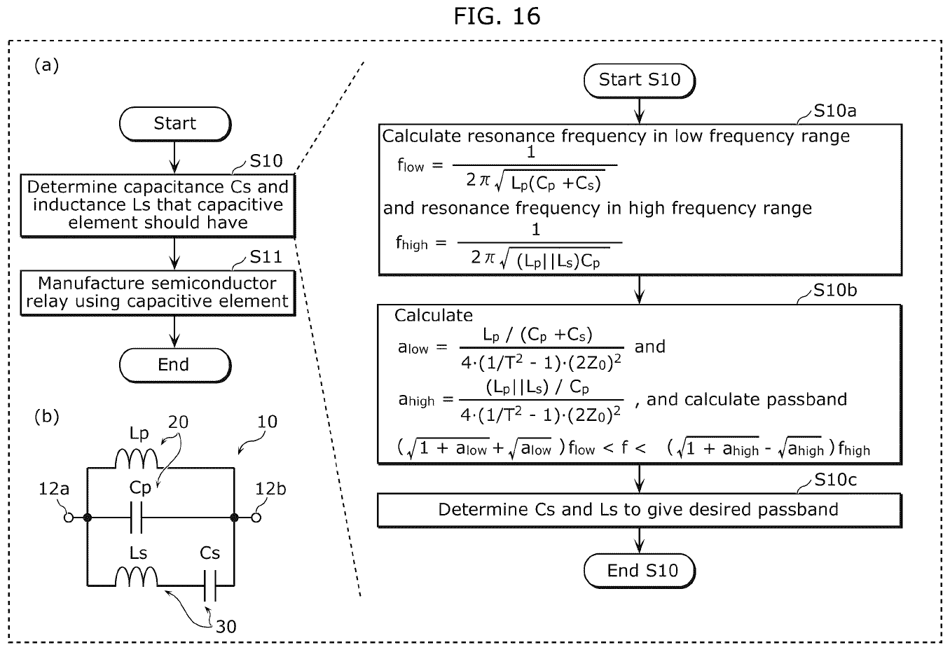

FIG. 16 is a diagram for illustrating a method of manufacturing semiconductor relay 10 according to an embodiment. More specifically, (a) of FIG. 16 is a flowchart illustrating a method of manufacturing semiconductor relay 10, and (b) of FIG. 16 is an equivalent circuit diagram of semiconductor relay 10 for reference and is identical to FIG. 2.

First, capacitance Cs and inductance Ls that capacitive element 30 included in semiconductor relay 10 should have are determined (Determination Step S10).

Next, using capacitive element 30 having capacitance Cs and inductance Ls determined, semiconductor relay 10 is manufactured with a semiconductor manufacturing apparatus and a part mounting apparatus (Manufacturing Step S11).

More specifically, in Determination Step S10, first, resonance frequency f_{low} of semiconductor relay 10 in a low frequency range and resonance frequency f_{high} thereof in a high frequency range, which are determined depending on capacitance Cs and inductance Ls that capacitive element 30 has, are calculated from expressions shown in Step S10a (S10a).

Then, using resonance frequency f_{low} in a low frequency range and resonance frequency f_{high} in a high frequency range calculated, passband f of semiconductor relay 10 is calculated from the expressions shown in Step S10b (S10b). Further, capacitance Cs and inductance Ls that capacitive element 30 should have are determined to make passband f calculated a desired passband (S10c).

Thereby, semiconductor relay 10 having a desired passband is manufactured.

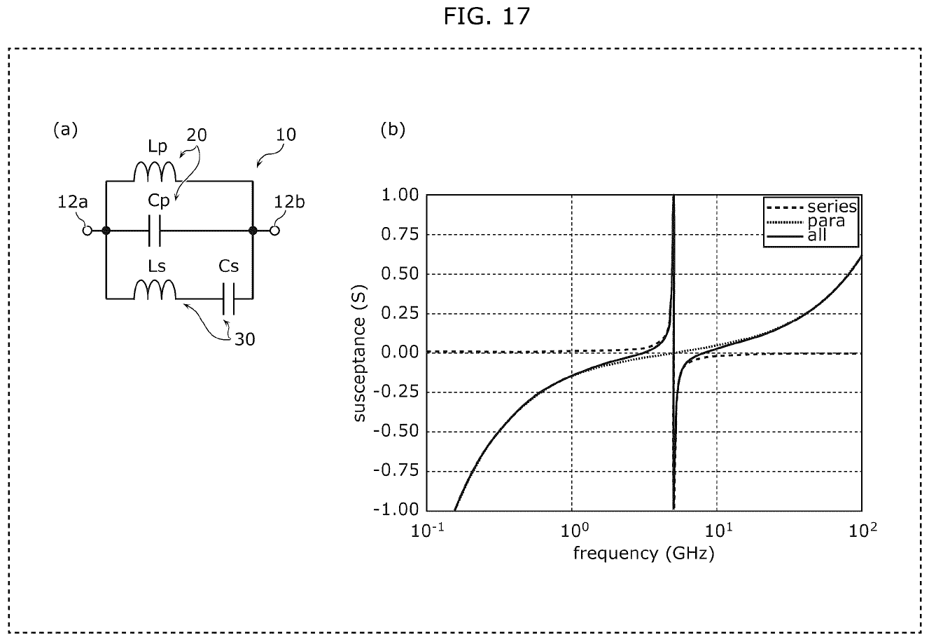

Here, the detailed procedure (S10a to S10c) of Determination Step S10 in the flowchart illustrated in FIG. 16, that is, the basic idea for determining capacitance Cs and inductance Ls that capacitive element 30 should have will be described with reference to FIGS. 17 to 19.

FIG. 17 is a diagram for illustrating a susceptance in an equivalent circuit of semiconductor relay 10 according to an embodiment. More specifically, (a) of FIG. 17 is an equivalent circuit diagram of semiconductor relay 10 for reference, and (b) of FIG. 17 is a diagram illustrating one example of frequency characteristics of the susceptance in the equivalent circuit of semiconductor relay 10. To be noted, (b) of FIG. 17 illustrates the susceptance in the serial circuit by capacitance Cs and inductance Ls (graph of “Series”), the susceptance in the parallel circuit by inductance Lp and capacitance Cp (graph of “Para”), and the susceptance in the entire equivalent circuit of the serial circuit in combination with the parallel circuit (graph of “All”), where Lp=1 nH, Cp=1 pF, Ls=1 nH, and Cs=1 pF.

Susceptance B (or the imaginary part of the admittance) of the equivalent circuit illustrated in (a) of FIG. 17 is represented by Expression 1 below.

$$B = 2 π fCp - 1 / 2 π fLp + 2 π fCs / ( 1 - {( 2 π f )}^{2} LsCs ) \qquad ( Expression 1 )$$

When susceptance B is 0 siemens, the signal cannot pass through the equivalent circuit. The above expression shows that 0 siemens always occurs at two points before and after serial resonance frequency fs=½π√LsCs. Thus, susceptance B of the equivalent circuit has frequency characteristics illustrated by the graph of “All” in (b) of FIG. 17, for example.

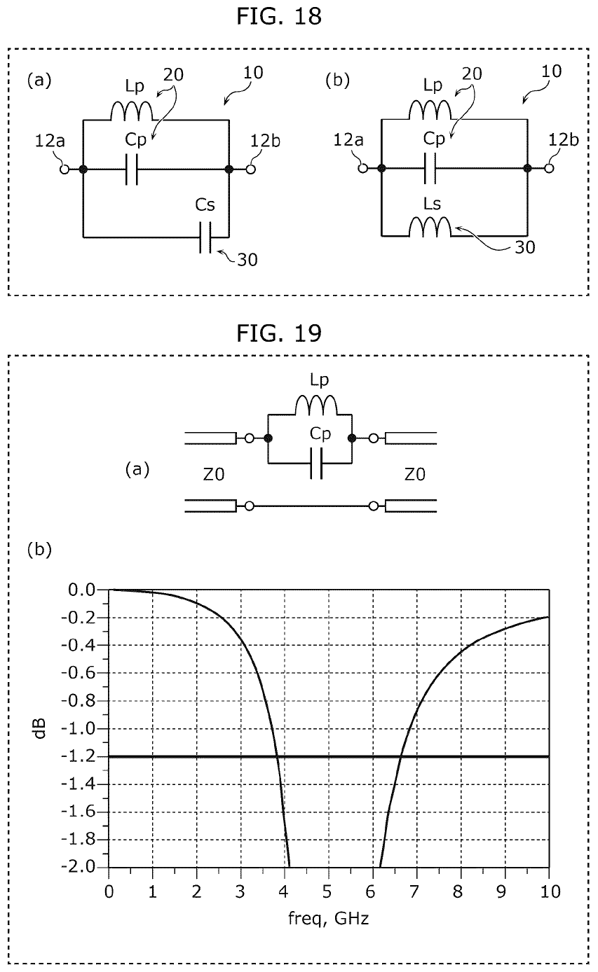

FIG. 18 is a diagram for illustrating frequencies at which two susceptances of 0 siemens appear in the equivalent circuit of semiconductor relay 10 according to an embodiment. More specifically, (a) of FIG. 18 is an equivalent circuit diagram when inductance Ls that capacitive element 30 has is neglected (regarded as short circuit) in the equivalent circuit of semiconductor relay 10, and (b) of FIG. 18 is an equivalent circuit diagram when capacitance Cs that capacitive element 30 has is neglected (regarded as short circuit) in the equivalent circuit of semiconductor relay 10.

Susceptance B of the equivalent circuit of semiconductor relay 10 is represented by Expression 1 above. Thus, f<½π√(LsCs) in a low frequency region is represented by Expression 2 below.

$$B \approx 2 π fCp - 1 / 2 π fLp + 2 π fCs \qquad ( Expression 2 )$$

As shown in Expression 2, susceptance B in a low frequency range does not include inductance Ls of capacitive element 30, and corresponds to the susceptance in the equivalent circuit illustrated in (a) of FIG. 18. In other words, frequency f in a low frequency range at which susceptance B represented by Expression 1 is 0 siemens is the resonance frequency of the parallel capacitance of Cp and Cs with Lp, and shifts to a lower frequency range due to an increase in Cs.

On the other hand, for f>½π√(LsCs) in a high frequency range, susceptance B in the equivalent circuit of semiconductor relay 10 is represented by Expression 3 below.

$$B \approx 2 π fCp - 1 / 2 π fLp - 1 / 2 π fLs \qquad ( Expression 3 )$$

As shown from Expression 3, susceptance B in a high frequency range does not include capacitance Cs of capacitive element 30, and corresponds to the susceptance in the equivalent circuit illustrated in (b) of FIG. 18. In other words, frequency f in a high frequency range at which susceptance B represented by Expression 1 is 0 siemens is the resonance frequency of the parallel inductance of Ls and Lp with Cp, and shifts to a higher frequency range due to a reduction in Ls.

FIG. 19 is a diagram for illustrating a method of determining a bandwidth to be used. More specifically, (a) of FIG. 19 illustrates an equivalent circuit in which an LC (here, LpCp) parallel resonance circuit is connected inside one of paired transmission lines of characteristic impedance Z0, and (b) of FIG. 19 illustrates one example of the pass characteristics of the equivalent circuit illustrated in (a) of FIG. 19.

For the LC parallel resonance circuit inside the transmission line of characteristic impedance Z0, frequency f at which pass characteristics S₂₁ (frequency characteristics of S parameter indicating the insertion loss) are greater than T (that is, the insertion loss is smaller than T) can be derived as in Expression 4.

$$[ Math . 1 ]$$

$${S}_{21} = \vert \frac{2 {Z}_{0}}{2 {Z}_{0} + \frac{j 2 π fL}{1 - {( 2 π f )}^{2} LC}} \vert > T \qquad ( Expression 4 )$$

Expression 4 is transformed into Expression 5 below.

$$[ Math . 2 ]$$

$$f < ( \sqrt{1 + a} - \sqrt{a} ) {f}_{r} , ( \sqrt{1 + a} + \sqrt{a} ) {f}_{r} < f \qquad ( Expression 5 )$$

$$However , {f}_{r} = \frac{1}{2 π \sqrt{LC}} , a = \frac{L / C}{4 \cdot ( 1 / {T}^{2} - 1 ) \cdot {( 2 {Z}_{0} )}^{2}}$$

As one example, where L=1 nH and C=1 pF, as shown in (b) of FIG. 19, pass characteristics S₂₁ are greater than-1.2 dB (T) (that is, the insertion loss is smaller than T) in the range of 3.8 GHz to 6.6 GHz.

Thus, capacitance Cs and inductance Ls that capacitive element 30 should have can be determined to make the passband of semiconductor relay 10 a desired passband (Steps S10a to S10c in (a) of FIG. 16).

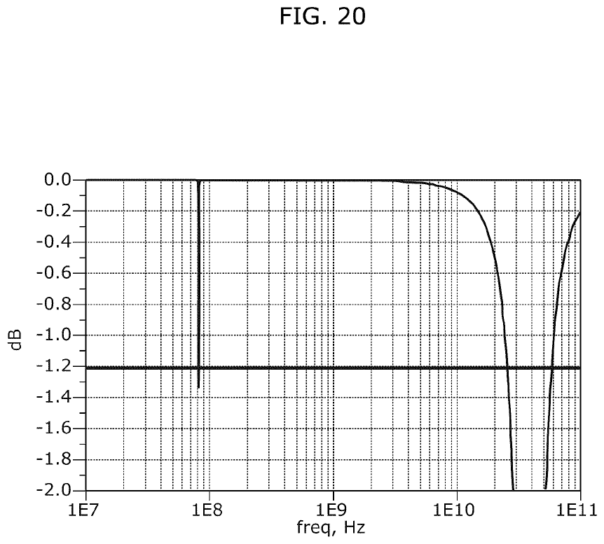

FIG. 20 is a diagram illustrating a specific example of the pass characteristics of semiconductor relay 10 in which capacitance Cs and inductance Ls that capacitive element 30 should have are determined according to Step S10 (S10a to S10c) in (a) of FIG. 16. Here, when Cp=0.085 pF and Lp=0.6 nH (that is, the resonance frequency is 22 GHz), Cs was 4.2 nF and Ls was 0.3 nH to satisfy pass characteristics S₂₁ of −1.2 dB or greater in a passband of 100 MHz to 25 GHz. The diagram illustrates the pass characteristics of semiconductor relay 10 at this time.

As above, the semiconductor relay and the semiconductor relay manufacturing method according to the present disclosure have been described based on the embodiments and Examples, but the present disclosure is not limited to these embodiments and Examples. The present disclosure also covers a variety of modifications of the present embodiments or Examples conceived and made by persons skilled in the art and other embodiments configured with a combination of part of the components in the embodiments and Examples without departing the gist of the present disclosure.

For example, in Examples 1 and 6 in which capacitive element 30 is disposed outside semiconductor element 20, capacitive element 30 is mounted on printed circuit substrate 40, but any other mount can be used. For example, capacitive element 30 may be directly connected between the output terminals of semiconductor element 20.

In Examples 7 to 9 in which inductance elements 50 and 51 are arranged inside semiconductor element 20, capacitive element 30 is disposed inside semiconductor element 20, but any other configuration can be used. Capacitive element 30 may be disposed outside semiconductor element 20.

### INDUSTRIAL APPLICABILITY

The semiconductor relay according to the present disclosure can be used as an inexpensive semiconductor relay having a simple configuration and having improved high-pass characteristics, for example, as a semiconductor relay including a PhotoMOS relay used between a pulse driver in a semiconductor tester and the DUT or as a semiconductor relay including a solid-state relay.

### REFERENCE SIGNS LIST

10, 10a to 10j semiconductor relay
11a first terminal (input terminal)
11b second terminal (input terminal)
12a third terminal (output terminal)
12b fourth terminal (output terminal)
20 semiconductor element
21 light emitting element
22 light receiving element
23 semiconductor chip
23a, 23b MOSFET
24 lead frame
30 capacitive element
40 printed circuit substrate
50, 51 inductance element
Lp inductance of semiconductor element
Cp capacitance of semiconductor element
Ls inductance of capacitive element
Cs capacitance of capacitive element

1. A semiconductor relay comprising:
input terminals including a first terminal and a second terminal;
output terminals including a third terminal and a fourth terminal;
a semiconductor element that provides electrical conduction and interruption between the output terminals in response to an electric signal given between the input terminals; and
a capacitive element connected between the output terminals,
wherein the capacitive element has a capacitance larger than a capacitance between the output terminals included in the semiconductor element, and
the capacitive element has an inductance smaller than an inductance between the output terminals included in the semiconductor element.

2. The semiconductor relay according to claim 1,
wherein the capacitive element is disposed outside the semiconductor element.

3. The semiconductor relay according to claim 1,
wherein the capacitive element is disposed inside the semiconductor element.

4. The semiconductor relay according to claim 3,
wherein the semiconductor element includes a lead frame, and
the capacitive element is formed with the lead frame included in the semiconductor element.

5. The semiconductor relay according to claim 3,
wherein the semiconductor element includes a semiconductor chip including a metal oxide semiconductor field-effect transistor (MOSFET), and
the capacitive element is formed inside the semiconductor chip.

6. The semiconductor relay according to claim 1, further comprising:
inductance elements that are inductors, resistors, or ferrite beads connected in series to the semiconductor element, between the output terminals.

7. The semiconductor relay according to claim 6,
wherein the inductance elements are arranged outside the semiconductor element.

8. The semiconductor relay according to claim 6,
wherein the inductance elements are arranged inside the semiconductor element.

9. The semiconductor relay according to claim 8,
wherein the semiconductor element includes a lead frame, and
the inductance elements are formed with the lead frame included in the semiconductor element.

10. A method of manufacturing the semiconductor relay according to claim 1, the method comprising:
determining a capacitance and an inductance that the capacitive element included in the semiconductor relay should have; and
manufacturing the semiconductor relay using the capacitive element having the capacitance and the inductance determined,
wherein in the determining,
a passband of the semiconductor relay is calculated using a resonance frequency of the semiconductor relay in a low frequency range and a resonance frequency of the semiconductor relay in a high frequency range that are determined depending on the capacitance and the inductance that the capacitive element has, and the capacitance and inductance that the capacitive element should have are determined to make the passband calculated a desired passband.
